(19) United States
(12) Patent Application Publication
(10) Pub. No.: US 2008/0246517 A1
(43) Pub. Date: Oct. 9, 2008

(54) Sample and Hold Circuits

(75) Inventors: Esther Olivia Rodriguez-Villegas, London (GB); Philip George Corbishley, London (GB)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: IMPERIAL COLLEGE INNOVATIONS LTD., London (GB)

(21) Appl. No.: 11/664,044

(22) PCT Filed: Sep. 28, 2005
(86) PCT No.: PCT/GB05/03740

§ 371 Date: Apr. 24, 2008

(30) Foreign Application Priority Data
Sep. 28, 2004 (GB) 0421535.6

(51) Int. Cl. G11C 27/02

(52) U.S. Cl. 327/94

(57) ABSTRACT

The voltage produced by an input current (iₙ) is sampled (S1, S2, S3) and stored on the gate (46) of a Fet (T1). The stored gate voltage allows the FET to function as the reference current source of a current mirror (T2, T3) which generates an output current (iₒᵤₜ) proportional to the sampled input current. The current mirror uses dual gate floating gate FETS (T2, T3) whose mirroring ratio can be finely adjusted by adjusting the bias voltages (V1, V2) applied to their auxiliary gate electrodes (425,435).

This invention relates to sample and hold circuits utilising current mirrors. It particularly relates to such circuits utilizing floating gate circuits. It more particularly relates to programmable floating gate circuits in which a floating gate is utilised in determining or programming the electrical parameters of a transistor. It still more particularly relates to such circuits used as programmable switching elements in switched current circuits.

One exemplary use of switched current (SI) circuits is to perform discrete time processing with analogue circuits. Applications include filters and various types of ADC and DAC converters. The constituent parts of these circuits, SI cells, may be designed to have a gain, α, such that the z-domain transfer function of the cell is

iₒᵤₜ=α.z^{-1/2}iᵢₙ (1)

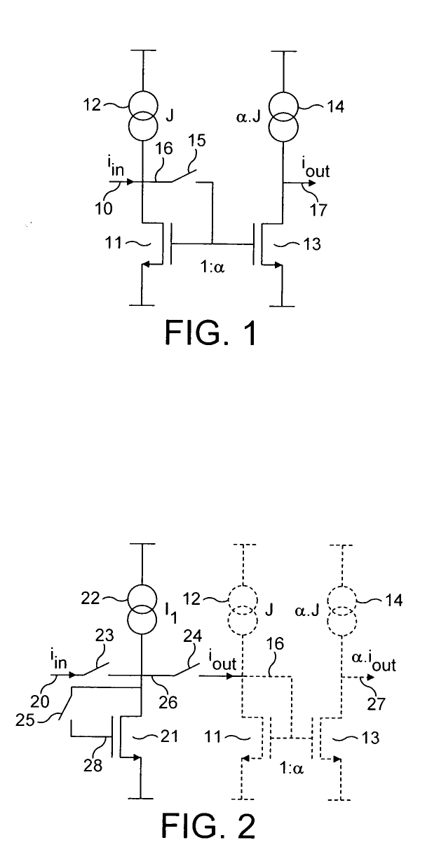

For a SI circuit the gains of the SI cells determine the overall transfer function. A common technique to create the gain coefficients within SI cells is to use current mirrors in various forms. In a prior art first generation cell, FIG. 1, the current mirror is part of the cell. First and second current sources 12, 14 supply currents J, α J to their associated current mirror—connected FETs 11, 13 which are dimensioned in the ratio 1:α in the conventional manner. The sum of input current iᵢₙ and current J flows through the source-drain path of FET 11 and in a sampling phase the resulting voltage on node 16 is coupled via switch 15 to the gates of FETS 11 and 13. This forces FET 13 to sink a current α(J+iᵢₙ) and thereby causes a current iₒᵤₜ equal to ζᵢₙ flow at output 17.

FIG. 2 shows a prior art second generation cell in which a single transistor is used for both input and output currents, so a current mirror after the output is required to provide the necessary gain. Current source 22 supplies a current to FET 21. In a sample mode, switches 23 and 25 are closed, and switch 24 is open. The sum of input current iᵢₙ on node 20 and current I₁ from current source 22 flows through the source-drain path of FET21, causing a voltage to be developed on node 28 i.e. the gate of FET 21. In the hold mode, switch 25 is opened, switch 23 is opened and switch 24 closed. The voltage formerly on node 28 remains impressed on node 28 causing a current iᵢₙ* (iᵢₙ during the sample phase) to flow to maintain the current I₁+iᵢₙ* in FET21. The necessary gain is produced by the subsequent circuitry which is identical in operation with FIG. 1 when switch 15 of FIG. 1 is in the closed state and will not be described further.

In these prior art circuits, the gain is determined at manufacture, current ratios being determined by the physical dimensions of the transistors. It is often useful, however, to be able to adjust coefficients within switched current circuits after manufacture to program them. This allows the characteristics of a circuit to be changed over time, for example to provide adaptive filtering or to tune the circuit accounting for device mismatch and process variation.

A number of possible programming schemes have been proposed. Programmability may be achieved with an array of circuits having different gains that are selectively switchable. A discrete number of gains are possible by switching in and out parts of the array. This technique, however, suffers from the limited size of the array. To increase the number of discrete values the gain may take, or resolution, requires increasingly more circuitry. Therefore this technique is only useful for a few discrete values of gain. Another approach uses multiplier circuits to alter the coefficients, offering a considerable range of gain and continuous programmability. A four quadrant multiplier built into a current cell and a separate multiplier after the SI cell have been proposed. However, a multiplier is required for every SI cell, therefore requiring considerable circuitry for each cell. Yet another approach uses transconductance amplifiers to program a circuit. FIG. 3 shows an example of what may be termed a first generation switched transconductance cell. An input current iᵢₙ at input 31 causes voltage to be developed at the output 33 of transconductance amplifier 32. When switch 33 is closed, this voltage is impressed on capacitor 34 causing transconductance amplifier 36 to output a current iₒᵤₜ. The gain, α, is varied by current I_{α}. This solution requires considerable circuitry and the programmability is of limited range. All these solutions either offer a limited resolution of gain or require considerable circuitry per current cell for programmability. In low power applications, where programmability is necessary, the large amounts of circuitry consume substantial power. This is undesirable.

The present invention seeks to provide an improved circuit arrangement in which the disadvantages of the prior art are at least ameliorated. The invention is set out in the claims.

Embodiments of the invention will now be described by way of non-limiting example only with reference to the drawings in which:

FIGS. 1. and 2. show examples of prior art switched current circuits;

FIG. 3 shows a prior art switched transconductance cell;

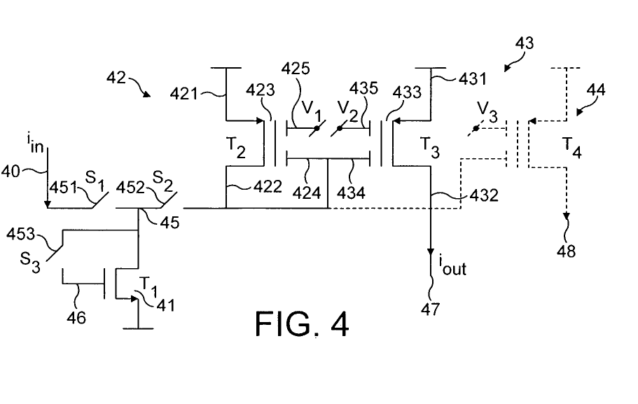

FIG. 4 shows a first embodiment of the invention comprising a programmable switched current floating gate cell (PSIFG);

FIG. 5 shows an equivalent circuit diagram of part of FIG. 4;

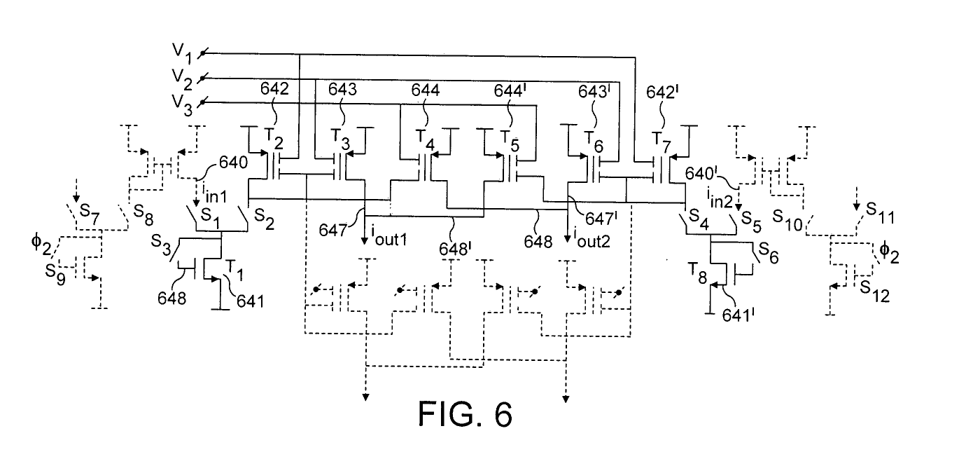

FIG. 6 shows a second embodiment of the invention comprising a differential PSIFG;

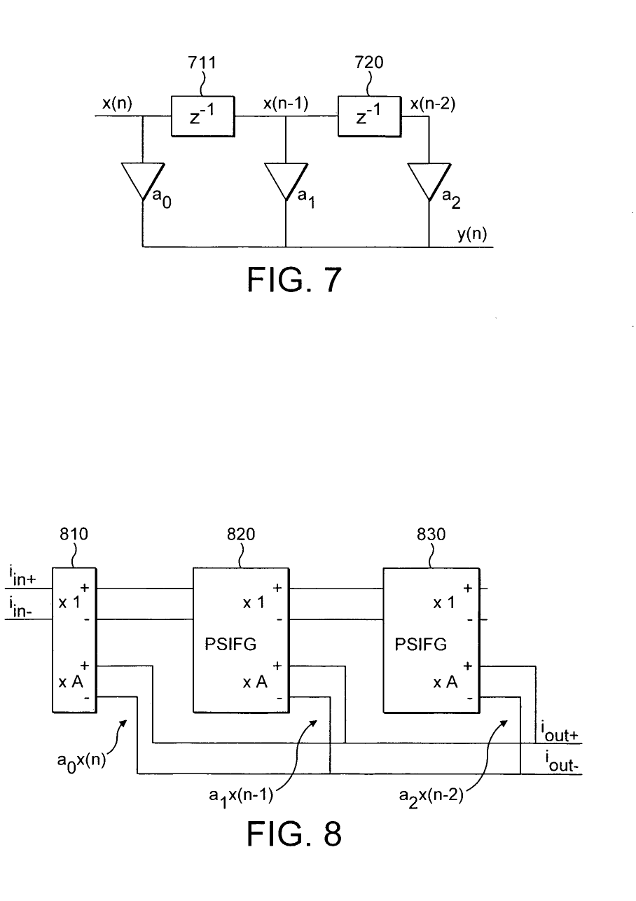

FIG. 7 shows a block diagram of a second order FIR filter;

FIG. 8 shows a block diagram of one way of implementing the filter of FIG. 7 in accordance with the invention;

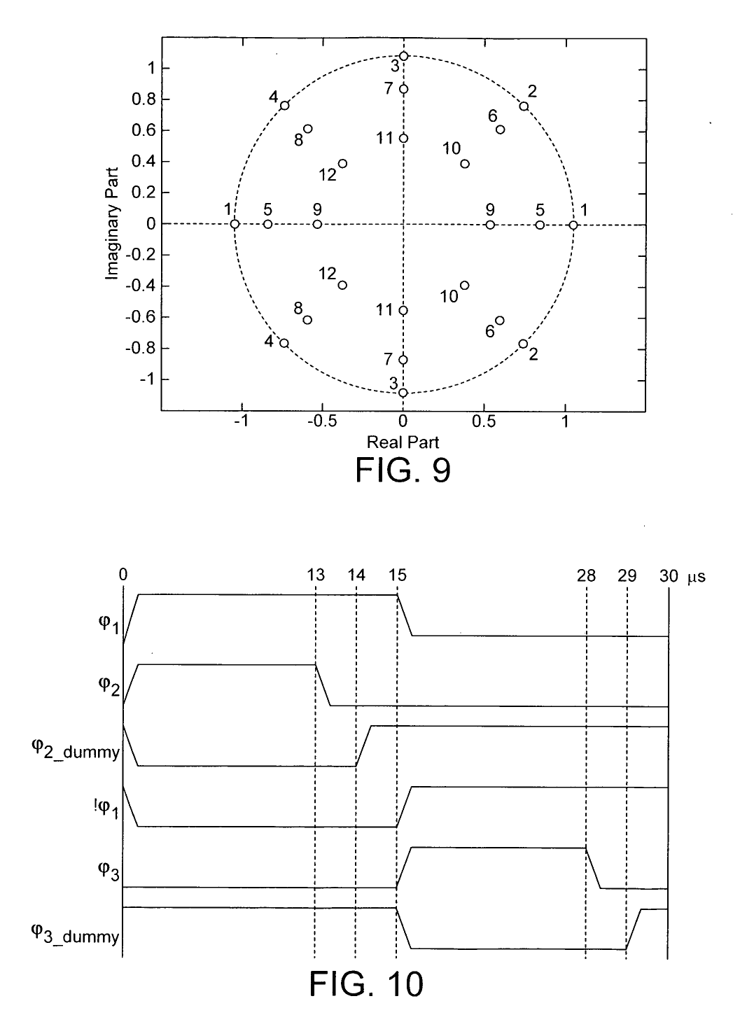

FIG. 9 shows a plot on the complex plane of the zeros of the filter of FIG. 7;

FIG. 10 shows a timing diagram of signals used in the circuit of FIG. 6; and

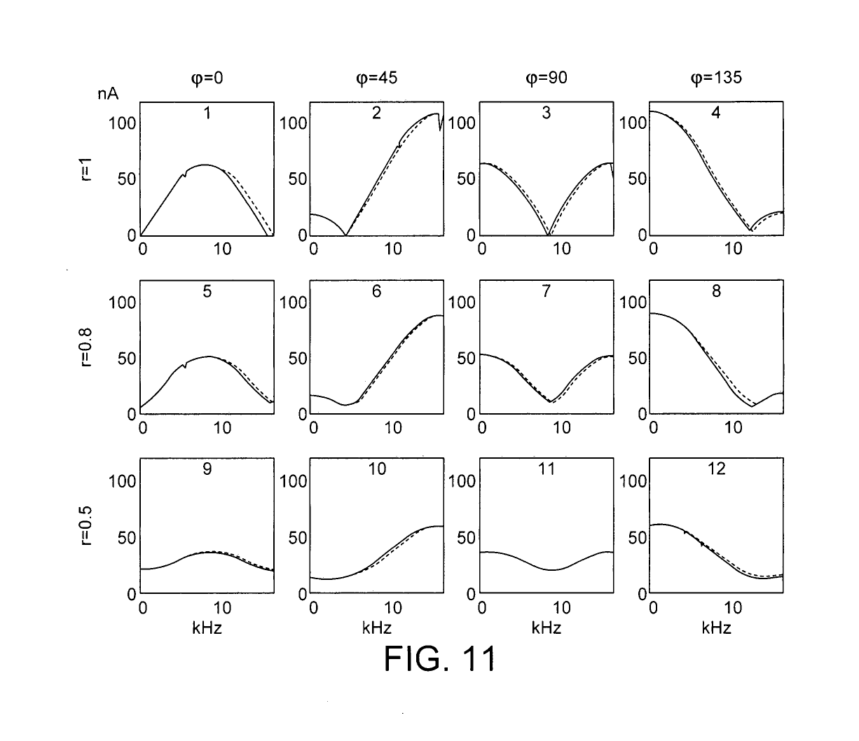

FIG. 11 shows plots of various transfer functions of the filter for various different values of selected coefficients;

Referring now to FIG. 4, a PSIFG in accordance with the invention comprises a first FET 41 (T1), a first floating gate arrangement 42 (T2), a second floating gate arrangement 43 (T3) and first second and third switches 451, 452, 453 respectively (S1, S2, S3).

An input current i₁ is applied at input node 40 and an output current iₒᵤₜ is obtained from output node 47. As shown in the phantom, one or more additional second floating gate arrangements 44 may be provided to produce additional outputs 48 if required.

T₁ provides the sample and hold element necessary for SI cells while T₂ and T₃ form a floating gate current mirror whose current gain is programmed by the bias voltages, V₁ and V₂. Switches S₁ and S₃ are closed and S₂ open during the sampling phase of the clock signal. The voltage on the gate 46 of T₁ is held during the second phase when S₁ and S₃ are opened and S2 closed. This clocking strategy is similar to a second generation SI cell previously described with reference to FIG. 2.

During the hold phase, T₁'s drain current is steered through the floating gate current mirror. While it is possible to implement the floating gate FET arrangements as single circuit components in which a floating gate overlies a channel region and is itself overlaid by two gate electrodes, in the present embodiment floating gate FETs arrangements are constructed in a CMOS process from a FET and a number of capacitors as in FIG. 4. FIG. 5 shows the circuit diagram of the floating gate arrangement 42. The other floating gate arrangements 43, 44 have the same configuration. For the two-input floating gate FETs used in this embodiment, two capacitors C_{G1} and C_{G2} are required. The floating gate voltage, V_{FG}, is given by the capacitances and terminal voltages, V_{G1} and V_{G2}, in accordance with the formula.

$${V}_{FG} = {V}_{G 1} \frac{{C}_{G 1}}{{C}_{T}} + {V}_{G 2} \frac{{C}_{G 2}}{{C}_{T}} + {V}_{B} \frac{{C}_{GB}}{{C}_{T}} + {V}_{S} \frac{{C}_{GS}}{{C}_{T}} + {V}_{D} \frac{{C}_{GD}}{{C}_{T}} , \\ where \\ {C}_{T} = {C}_{G 1} + {C}_{G 2} + {C}_{GB} + {C}_{GS} + {C}_{GD} . \qquad ( 2 )$$

All symbols—capacitances and voltages—associated with the FET have their usual meanings. Assuming that C_{GB}, C_{GS} and C_{GD}, are considerably smaller than C_{G1} and C_{G2} these terms may be neglected, hence:

$${V}_{FG} = α {V}_{G 1} + β {V}_{G 2} \\ where \\ α = \frac{{C}_{G 1}}{{C}_{G 1} + {C}_{G 2}} , β = \frac{{C}_{G 2}}{{C}_{G 1} + {C}_{G 2}} . \qquad ( 3 )$$

In this embodiment the floating gate transistors are operated in weak inversion. This allows a current consumption to be in the order of nanoamps. Now, using the FET in weak inversion the drain current, I_{D}, in saturation is given by

$$\begin{matrix}{I}_{D} = {I}_{S} exp ( \frac{{V}_{FG} - {V}_{TO} - {nV}_{S}}{{nU}_{T}} ) \\ = {I}_{S} exp ( \frac{α {V}_{G 1} + β {V}_{G 2} - {V}_{TO} - {nV}_{S}}{{nU}_{T}} )\end{matrix} \qquad ( 4 ) , ( 5 )$$

Where V_{TO}, U_{T}, I_{S} and n are the threshold voltage, thermal voltage, specific current and slope factor respectively. Applying equation (5) to T₂ and T₃ of FIG. 4 and considering the effect of delay in the cell, equation (1), the overall transfer function is:

$${i}_{out} = {z}^{- 1 / 2} \cdot {i}_{i n} \cdot exp ( \frac{β ( {V}_{2} - {V}_{1} )}{{nU}_{T}} ) . \qquad ( 6 )$$

Thus, by altering V₁ and V₂ the gain of the cell may be changed.

In a second embodiment of the invention the basic PSIFG cell may be extended to a differential version, which in its basic form consists of the solid lines of FIG. 6. The cell is formed from two basic PSIFG cells: T₁, T₂ and T₃ form one cell and T₆, T₇ and T₈ form another. In general, items referenced 64× corresponds with items referenced 4× in FIG. 4. Current iₒᵤₜ₁ consists of the sum of the output 647 of the left-hand cell and the output 648 of the right-hand cell. Output iₒᵤₜ₂ consists of the sum of the output 647 of the right-hand cell and the output 648 of the left-hand cell. Transistors T₄ and T₅ extend the respective floating gate current mirrors, giving the differential PSIFG cell its principle advantage—the gain may be both positive and negative, unlike the simple PSIFG cell with only positive gain. This may be observed in the mathematics, where the expressions for the output currents, Iₒᵤₜ₁ and Iₒᵤₜ₂, are:

$${I}_{out 1} = {z}^{- 1 / 2} {I}_{i n 1} exp ( \frac{β ( {V}_{2} - {V}_{1} )}{{nU}_{T}} ) + {z}^{- 1 / 2} {I}_{i n 2} exp ( \frac{β ( {V}_{3} - {V}_{1} )}{{nU}_{T}} ) \\ {I}_{out 2} = {z}^{- 1 / 2} {I}_{i n 1} exp ( \frac{β ( {V}_{3} - {V}_{1} )}{{nU}_{T}} ) + {z}^{- 1 / 2} {I}_{i n 2} exp ( \frac{β ( {V}_{2} - {V}_{1} )}{{nU}_{T}} ) \qquad ( 7 ) , ( 8 )$$

Hence the differential output, Iₒᵤₜ, is given by

$$\begin{matrix}{I}_{out} = {I}_{out 1} - {I}_{out 2} \\ = {z}^{- 1 / 2} ( {I}_{i n 1} - {I}_{i n 2} ) ( exp ( \frac{β ( {V}_{2} - {V}_{1} )}{{nU}_{T}} ) - exp ( \frac{β ( {V}_{3} - {V}_{1} )}{{nU}_{T}} ) ) .\end{matrix} \qquad ( 9 )$$

Thus, when V₂>V₃ the cell's gain is positive and when V₂<V₃ it is negative. In a modification, two extensions can be added to the differential PSIFG cell as shown by the dotted sections of FIG. 6 in which additional outputs are produced by extending the floating gate current mirror. In a first modification an extra switched circuit may be added at the inputs to create a full unit delay, z⁻¹ doubling the z^{-1/2} already present. This solution for programmable SI cells is advantageous as it does not require any form of transconductance or operational amplifier for each cell, reducing power consumption and it provides a continuous step free gain factor unlike array switching where gain can be altered in discrete steps.

The invention has many applications. One exemplary non-limiting field of application is in the implementation of filters. One such example will now be described with reference to FIGS. 7-11.

The equation for a second order FIR filter is

y(n)=α₀x(n)+α₁x(n−1)+α₂x(n−2). (10)

This, in the form of a block diagram may be seen in FIG. 7. Two PSIFG cells 711, 720 are required, both with a full unit delay and one with a double set of outputs as shown in FIG. 8. The block diagram of an implementation of FIG. 7 in accordance with the invention is shown in FIG. 8. A floating gate current mirror 810 is used at the input of the system to provide coefficient a₀ from input signal iᵢₙ₊, iᵢₙ₋ without any delay added. A first PSIFG cell 820 having a double set of outputs generates at a first output the function a₁ x (n−1) from the output of current mirror 810. Its second output provides an input to the second PSIFG cell 830 having a single set of outputs at which the signal a₂x(n−2) is produced. The output currents of the lower sets of outputs of circuit blocks 810, 820, 830 are summed in known manner on a single pair of lines to produce the desired output currents iₒᵤₜ₊, iₒᵤₜ₋ which represent the desired function given in equation (10) above.

In the z domain the transfer function for a second order FIR filter is

$$T ( z ) = \frac{Y ( z )}{X ( z )} = {a}_{0} + {a}_{1} {z}^{- 1} + {a}_{2} {z}^{- 2} . \qquad ( 11 )$$

Thus for a₂, a₁, a₀ to be real, the roots of T(z) are either a complex conjugate pair or both real, the roots of T(z) being the zeros for the system. For a pair of complex conjugate roots of radii r and at angles ±φ, the coefficients are

α₁=−2α₀·r cos(φ) (12)

α₂=α₀·r, (13)

where a₀ is chosen as a suitable scaling factor given the range of gains from the floating gate current mirrors. The two poles of the system are located at the origin making the filter inherently stable.

The filter may be physically implemented using a standard analogue CMOS process for example AMS 0.35 um CSD with BSIM3v3 FET models in Cadence.

To test the filter, a range of values for r and φ were chosen, r=0.5, 0.8 and 1, φ=45, 90, 135 degrees. In addition 3 points for the real valued zeros on the real axis were chosen, with zero pairs at: 1, −1; 0.8, −0.8; and 0.5, −0.5. All the zero positions may be seen in FIG. 9. The numbers correspond to each pair of zeros, for identification. With a₀ set to 0.5, table 1 shows the values of a₁ and a₂ where the zeros position number corresponds to the numbers in FIG. 9.

TABLE 1

| Zero Position | | | | |
|---|---|---|---|---|
| Number | Radius(r) | φ | a₁ | a₂ |
| 1 | 1 | 0 (and 180) | 0 | 0.5 |
| 2 | 1 | 45 | −0.707 | 0.5 |
| 3 | 1 | 90 | 0 | 0.5 |
| 4 | 1 | 135 | 0.707 | 0.5 |
| 5 | 0.8 | 0 (and 180) | 0 | 0.32 |
| 6 | 0.8 | 45 | −0.566 | 0.32 |
| 7 | 0.8 | 90 | 0 | 0.32 |
| 8 | 0.8 | 135 | 0.566 | 0.32 |
| 9 | 0.5 | 0 (and 180) | 0 | 0.125 |
| 10 | 0.5 | 45 | −0.354 | 0.125 |
| 11 | 0.5 | 90 | 0 | 0.125 |
| 12 | 0.5 | 135 | 0.354 | 0.125 |

FIG. 10 is a timing diagram for the various clocks signals used in the simulation. The switches controlled by φ₁ and !φ₁ are S₁, S₂, S₄, S₅, S₇, S₈, S₁₀ and S₁₁ of FIG. 6. Signal 2 controls switches S9 and S12, signal φ₃ controls switches S₃ and S₆.

Transfer functions for a FIR filter with the various coefficients are shown in FIG. 11. The ideal response is dotted, the simulated response is a continuous line. The numbers of each plot correspond to the numbers of each pair of zeros on the z domain plot, of FIG. 9. Columns show the zeros with radii 1, 0.8 and 0.5 from top to bottom. Rows show the zeros as they move around the unit circle, 0 (and 180), 45, 90, and 135 degrees from left to right. A number of modifications are possible within the scope of the invention.

While in the embodiment of FIG. 4 both T3 and T4 have floating gate arrangements, it may be possible to replace one of T3 and T4 by a conventional FET if the other has sufficient adjustability to cope with the requirements of a particular application.

The bandwidth attainable by systems in accordance with the invention is suitable for audio applications or indeed any application requiring the generation of accurately determinable, continuously-variable current gains, or gains that need to be accurately adjusted over a continuous range of values in a non-stepwise manner.

1. A sample and hold circuit comprising:
means to sample an input current and to generate a sample current at a first common node representing the sampled input current;
programmable current mirror means having a current input connected to said first common node to be responsive to said sample current and arranged to generate an output current proportional to said sample current;
said current mirror means comprising means for adjusting the gain of the current mirror.

2. A circuit as claimed in claim 1 in which the programmable current mirror means comprises FET means
including at least one FET having a galvanically isolated floating gate electrode having at least one control electrode capacitively coupled thereto.

3. A circuit as claimed in claim 2 in which the FET means includes at least one second FET having a galvanically isolated floating gate electrode having at least one control electrode capacitively coupled thereto and comprising first and second control electrodes, wherein the capacitively coupled control electrodes are arranged such that the first control electrode operates as a functional gate electrode of the at least one FET, and the second control electrode operates as a bias electrode; and further comprising
bias voltage source means coupled to the second control electrode, the first control electrode being connected to the gate electrode or functional gate electrode of the at least one second FET and to the drain electrode of one of the FETS at a second common node such that the current ratio of the current mirror can be adjusted by adjusting the bias voltage.

4. A circuit as claimed in claim 3 including at least one further second FET means, the or each further FET means functioning as a respective current mirroring element, characterised in that the or each further second FET means comprises a further FET arrangement having a further functional gate electrode coupled to the second common node and a further control electrode such that the current mirror ratio of the further second FET arrangement can be adjusted by adjusting the bias voltage applied thereto.

5. A circuit as claimed in claim 1, characterised in that the means to sample comprises a field effect transistor having a source, a drain and a gate electrode; first, second and third switch means, the first means connected between a source of input current and the drain electrode, the second switch means connected between the drain electrode and the second common node, the third switch means connected between the drain electrode and the gate electrode, means to operate the switches such that, in a sample mode, the third and second switches are closed and to the second switch is open so as to impress on the gate electrode a voltage relating to the current in the source-drain path, and that in a hold mode the position of the switches is reversed so as to retain on the gate electrode a voltage which causes the previously-existing source-drain current to remain at its former level and to sink this current from the common node.

6. A circuit comprising first and second circuits according to claim 4 comprising:
means to supply respective first and second balanced input signals to respective said first inputs:
means to combine the output current of the second FET of the first circuit with the output current of the further second FET of the second circuit;
means to combine the output current of the further second FET of the first circuit with the output current of the second FET of the second circuit;
bias means being operative to apply a first bias voltage to the control electrode means of both second FET means; and
to apply a second bias voltage to the control electrode means of both further second FET means.

7. A circuit as claimed in claim 2, characterised in that the means to sample comprises a field effect transistor having a source, a drain and a gate electrode; first, second and third switch means, the first means connected between a source of input current and the drain electrode, the second switch means connected between the drain electrode and the second common node, the third switch means connected between the drain electrode and the gate electrode, means to operate the switches such that, in a sample mode, the third and second switches are closed and to the second switch is open so as to impress on the gate electrode a voltage relating to the current in the source-drain path, and that in a hold mode the position of the switches is reversed so as to retain on the gate electrode a voltage which causes the previously-existing source-drain current to remain at its former level and to sink this current from the common node.

8. A circuit as claimed in claim 3, characterised in that the means to sample comprises a field effect transistor having a source, a drain and a gate electrode; first, second and third switch means, the first means connected between a source of input current and the drain electrode, the second switch means connected between the drain electrode and the second common node, the third switch means connected between the drain electrode and the gate electrode, means to operate the switches such that, in a sample mode, the third and second switches are closed and to the second switch is open so as to impress on the gate electrode a voltage relating to the current in the source-drain path, and that in a hold mode the position of the switches is reversed so as to retain on the gate electrode a voltage which causes the previously-existing source-drain current to remain at its former level and to sink this current from the common node.

9. A circuit as claimed in claim 4, characterised in that the means to sample comprises a field effect transistor having a source, a drain and a gate electrode; first, second and third switch means, the first means connected between a source of input current and the drain electrode, the second switch means connected between the drain electrode and the second common node, the third switch means connected between the drain electrode and the gate electrode, means to operate the switches such that, in a sample mode, the third and second switches are closed and to the second switch is open so as to impress on the gate electrode a voltage relating to the current in the source-drain path, and that in a hold mode the position of the switches is reversed so as to retain on the gate electrode a voltage which causes the previously-existing source-drain current to remain at its former level and to sink this current from the common node.

10. A circuit comprising first and second circuits according to claim 9 comprising:
means to supply respective first and second balanced input signals to respective said first inputs:
means to combine the output current of the second FET of the first circuit with the output current of the further second FET of the second circuit;
means to combine the output current of the further second FET of the first circuit with the output current of the second FET of the second circuit;
bias means being operative to apply a first bias voltage to the control electrode means of both second FET means; and
to apply a second bias voltage to the control electrode means of both further second FET means.
